(19) United States
(12) Patent Application Publication
(10) Pub. No.: US 2023/0087704 A1
(43) Pub. Date: Mar. 23, 2023

(54) DEVICE FOR TESTING AT LEAST ONE PLUG-IN ELEMENT

(71) Applicant: Kistler Holding AG, Winterthur (CH)

(72) Inventors: Reinhold Buck, Illnau (DE); Davorin Konic, Huettikon (CH); Patrick Dudler, Schweiz (CH); Martin Giger, Winterthur (CH)

(21) Appl. No.: 17/947,439

(22) Filed: Sep. 19, 2022

(30) Foreign Application Priority Data
Sep. 20, 2021 (EP) 211997789.7

(51) Int. Cl. G01R 1/04; G01R 31/66

(52) U.S. Cl. CPC G01R 1/0416; G01R 31/66

(57) ABSTRACT

A device for testing at least one plug-in element includes a plug-in element receptacle and a test element receptacle, which are adapted to be movable along a test axis for establishing a plug-in connection. A force sensor is configured and disposed to detect a force along the test axis when the plug-in connection is established. A compensating element is configured and disposed for compensating for an offset between the plug-in element and a test element. The compensating element is configured to be at least partially elastic so that the test element is elastically movable to compensate for alignment deviations from the test axis. A method for testing at least one plug-in element is provided along with a method for producing the compensating element.

### TECHNICAL FIELD

The invention relates to a device for testing at least one plug-in element of a plug-in connection. The invention also relates to a method for testing plug-in elements of a plug-in connection. The invention further relates to the use of a compensating element according to the invention in a device for testing plug-in elements of a plug-in connection. Furthermore, the invention relates to the production of a compensating element according to the invention for use in a device for testing plug-in elements of a plug-in connection.

### BACKGROUND OF THE INVENTION

Plug-in connections are used in a variety of applications. Thus, plug-in connections are, for example, known in the electrical industry from electrical plug-in connections for connecting electrically conductive elements and establishing an electrical contact. However, plug-in connections are also known from other areas such as for example pipeline construction where two pipes are connected by plugging them together forming a continuous pipeline. Plug-in elements are also known in the optical industry, for example for connecting optical lines. Optical lines are so-called optical fibers, for example.

In the electrical industry, connections between two plug-in elements, so-called plug-in connections, are often configured to be reversible and a plug-in connection is made of two plug-in elements. A first plug-in element is connected to another plug-in element by joining. This process is generally also referred to as plugging or inserting. In the following, the term plug-in element is understood to mean a plug-in element that forms a plug-in connection with a matching further plug-in element by joining the plug-in element and the further plug-in element. In general, joining is a linear movement.

For establishing a plug-in connection, the plug-in element is properly aligned with the further plug-in element whereafter they are joined to precisely fit to each other. The plug-in connection often is a force-locking and releasable connection. This is, for example, achieved by using a plug-in element that exerts a spring force onto the further plug-in element. Alternatively, the further plug-in element may exert a spring force onto the plug-in element.

Therefore, for establishing a plug-in connection a force must be applied by which the plug-in element is pressed into the further plug-in element. This force is called the insertion force.

For disconnecting a plug-in connection, a force must be applied by which the plug-in element is pulled out of the further plug-in element of the plug-in connection. This force is referred to as the extraction force, the pull-out force or the withdrawal force.

The insertion and extraction forces vary depending on the application. For plug-in connections not subjected to mechanical stresses, for example due to an acceleration of the assembly that comprises the plug-in connection, the extraction forces are known to be small; in the order of a few 100 mN (millinewtons). However, for plug-in connections subjected to high mechanical stresses, extraction forces of several 100 N (newtons) are known. Extraction forces are also known to be part of DIN EN 60512-1-100_2012.

Therefore, in the production of plug-in connections, it is essential to have an insertion force and an extraction force of a plug-in connection that do not differ from an insertion force nominal value or an extraction force nominal value, respectively, by more than an insertion force tolerance or an extraction force tolerance.

Thus, it is necessary to test the insertion force and/or the extraction force of plug-in connections to ensure high quality plug-in connections. For this purpose, a plug-in element is inserted into a further plug-in element and the force required for establishing the plug-in connection is measured. The force determined in this plug-in connection test must be within a predefined range specified for a high quality plug-in connection.

Such a test is known from EP0703646A2. A plug-in end of a conductor being the test element is inserted by means of a gripper into a point of connection being the plug-in element. The gripper is a test element receptacle. The test element receptacle is mounted on a force transducer which determines an insertion force when the plug-in connection is established. For testing the connection, a force acting in the direction opposite to the insertion force is applied up to a nominal value of a conductor holding force, shortly referred to as holding force, which is less than the nominal value of the extraction force. The plug-in connection meets the requirements when the plug-in connection is not released. The insertion force and/or the extraction force between the plug-in element and the test element is tested. In the following, the term plug-in element is used to refer to the plug-in element to be tested.

A plug-in element or a test element may be a female or a male element in which case the mating further plug-in element of the plug-in connection will be a corresponding male or female element, respectively. In addition, a plug-in element may also be neither a male nor a female element and in this case the further plug-in element of the plug-in connection is also neither a male nor a female element.

In general, the male plug-in element of a plug-in connection comprises outwardly facing contact pins. Often, a contact pin is also referred to as a pin. Usually, the female mating element comprises inwardly facing contact openings. The male plug-in element is generally also known as a plug or built-in plug. The female plug-in element is generally also known as a socket or coupling.

The insertion force and the extraction force are each defined in a test axis along which the plug-in connection is established or released. The plug-in and test elements are arranged along the test axis for establishing or releasing a plug-in connection. If the test element or the plug-in element is offset from the test axis, the insertion force will not be determined correctly.

Establishing or releasing a plug-in connection is also referred to as plugging a plug-in connection.

In the production of plug-in connections, the extraction force and/or the insertion force of the plug-in element produced, is at least randomly tested by using a suitable test element. The test element has predetermined dimensions and properties. In this way, wear and tear of the production machine and/or the tool or improper setting of the machine may be detected and rejects of produced plug-in elements that are not within the range of the insertion force tolerance or the extraction force tolerance of the insertion force nominal value or the extraction force nominal value may be avoided.

The use of a force sensor for determining an insertion force is well-known. However, it is a disadvantage that transverse forces that are not coaxial with the designated insertion force or extraction force may act on the force sensor and falsify the insertion force or extraction force measurement. Transverse forces occur when the plug-in element and the test element are not precisely aligned with one another during establishment of the plug-in connection. Not precisely aligned may refer to a parallel offset of the test element or the plug-in element from the test axis.

The insertion force or the extraction force cannot be accurately determined when an asymmetrical load acts on the plug-in element. In the case of an offset between the plug-in element and the test element in a direction perpendicular to the test axis, a transverse force as already mentioned above occurs when establishing the plug-in connection. This leads to excessive deformation on one side of the plug-in element while the load onto the other side of the plug-in element is correspondingly lower. This results in a change in friction and a resulting alteration of the force required for establishing the plug-in connection. An offset between the plug-in element and the test element leads to an alteration of the required force, since the spring element that normally connects the plug-in and test elements by a force-fitting connection by means of a spring force often is not linear with the deflection of the spring element. In general, the linear spring deflection of a socket is a fraction of the diameter of a contact pin. If one side of the plug-in contact or the test element is deflected more than the permissible spring deflection due to an offset, this deflection has an impact on the force required for plugging the plug-in connection. The permissible spring deflection is given by the requirement that the spring force of the spring must remain in the linear range according to the equation F=d·a wherein F is the spring force, a is the deflection and d is the spring constant. This relationship is known as Hooke's law.

Imprecise alignment also may be caused by a tilt with respect to the test axis of at least one of the connecting element and the counter element. In this case, axial forces arise in addition to the transverse forces, due to the angular error, whereby the measurement is further falsified.

### OBJECTS AND SUMMARY OF THE INVENTION

It is an object of the present invention to alleviate the impact that disturbing forces have on the determination of the insertion force and/or the extraction force. It is another object of the invention to compensate for an offset between the test element and the plug-in element.

These objects and others have been achieved by the features described hereinafter.

The invention relates to a device for testing at least one plug-in element; comprising a test element that is pluggable into the plug-in element for performing the test; comprising a plug-in element receptacle in which a plug-in element is arranged; comprising a test element receptacle in which the test element is arranged; wherein the plug-in element receptacle and the test element receptacle are arranged movably along a test axis for establishing the plug-in connection; comprising a force sensor configured to determine a force that occurs when the plug-in connection is established along the test axis and to provide said force in the form of a force signal; characterized in that said device comprises a compensating element for compensating for an offset between the plug-in element and the test element; in that the compensating element is at least partially elastic along at least one spatial axis; in that the test element receptacle is arranged in an operative connection with the compensating element in such a way that the test element is elastically movable along said spatial axis.

A plug-in element is tested by means of a test element. For testing a plug-in element, the plug-in element is arranged in the plug-in element receptacle and secured by a securing element. The securing element may be a spring that secures the plug-in element in the plug-in element receptacle by means of a force-fitting connection. The securing element may also be a screw that secures the plug-in element in the plug-in element receptacle in a force-fitting manner. A test element configured to form a plug-in connection with the plug-in element is secured in the test element receptacle. For example, the test element is shaped like a pin when the plug-in element is shaped like a socket. Establishing the plug-in connection between the plug-in element and the test element is performed along the test axis. Ideally, the arrangement of the test element in the test element receptacle and that of the plug-in element in the plug-in element receptacle is such that the plug-in element and the test element are arranged coaxially to each other and furthermore coaxially with respect to the test axis along which the test element receptacle and the plug-in element receptacle are movable. In this case, an insertion force may be determined without any interference since the plug-in element and the test element are aligned with one another in the best possible way. In practice, however, there is always an offset or tilt between the plug-in element and the test element. This offset has an impact on the determination of the insertion force and/or the extraction force so that not the minimum insertion force and/or minimum extraction force is determined. For this reason, the insertion and extraction forces of different plug-in elements cannot be compared since the insertion force is dependent on the offset which is different each time a plug-in element is inserted in the plug-in element receptacle. The compensating element is adapted to compensate for this offset or tilt. This compensation is achieved by using a flexible compensating element. If there is an offset between the plug-in element and the test element when the connection is established, they will align coaxially with each other upon contact since the compensating element is elastically deformed by the transverse force that occurs in the event of a tilt or an offset. However, this is only true for an offset of an amount that still enables the plug-in element and the test element to be connected to one another. It is not possible to compensate an offset of more than half the diameter of the plug-in element or the test element without using additional measures.

Advantageously, a time between the completion of the production of the plug-in element and the testing of the plug-in element is only a few seconds to hours. In the event that a plurality of plug-in contacts do not meet the requirements there may be a problem in the production, for example incorrect dimensions of the plug-in contact or choice of an inappropriate material. For quickly solving the problem in the course of production and avoiding the production of a large number of defective plug-in contacts, it is particularly advantageous to keep the time period as short as possible, i.e., between a few seconds to minutes.

Testing a plug-in element by a device for testing plug-in elements according to the invention comprises the following steps of:
a) providing the test element receptacle at a position on the test axis;
b) providing the plug-in element receptacle at a position on the test axis;
c) moving the test element by the adjustment mechanism along the test axis in the direction towards the plug-in element;
d) continuously determining the force signal and the distance signal;
e) the force signal increases upon contact of the test element and the plug-in element; the compensating element compensates for a misalignment of the test element and the plug-in element and the insertion force is determined as a function of the force signal across the distance and is provided; and
f) comparing the insertion force at a predetermined nominal plug-in depth to a nominal insertion force.

A signal, in particular a force signal, is a sequence of discrete force values generated over a time interval. There is an increase in a force signal when the force value changes from a value of zero to a finite value. A finite value is different from zero or the zero position, respectively, when it exceeds a noise signal that is characteristic of the force signal. A movement of the test element may exert a force onto the force sensor due to the inertial mass of the test element and may generate a force signal that is close to zero. This is not understood as being an increase in the force signal. Accordingly, a decrease in a force signal occurs when the force value changes from a finite value to a value of zero.

In the event that the insertion force does not correspond to the nominal insertion force within a nominal insertion force tolerance range, then the plug-in element will be discarded for being defective. A rejected plug-in element is also referred to as a reject. If the number of rejects exceeds a predefined number, then the production line will be checked and adjusted, if necessary. The method is suitable for detecting problems arising in the production of plug-in elements quickly and at an early stage.

The method may be used for inspecting all plug-in elements produced, or it may be used for inspecting a subset of all plug-in elements produced.

In one embodiment of the method, the electrical conductance between the test element and the plug-in element is determined continuously by a conductance meter as a function of the distance and this conductance information is provided. This additional information regarding the conductance makes it possible to determine at which distance the plug-in element and the test element are in contact. Advantageously, it is further possible to determine whether the conductance is within a conductance tolerance range. In the event that the conductance is not within the conductance tolerance range, this deviation may indicate a problem in the production of the plug-in contact. This problem may include, as an example and not exhaustively, contamination of the plug-in element, insufficient cleaning of the plug-in element, corrosion of the plug-in element. In addition, an insufficient conductance may be caused by an insufficient insertion force, which may be directly detected from the force signal.

### BRIEF DESCRIPTION OF THE SEVERAL VIEWS OF EXEMPLARY DRAWINGS

In the following, the invention is explained in more detail by way of example with reference to the figures in which:

FIG. 1 shows a schematic partial view of an embodiment of a device for testing plug-in elements of a plug-in connection;

FIG. 2 shows a schematic partial view of a further embodiment of a device for testing plug-in elements of a plug-in connection;

FIG. 3 shows a schematic partial view of an embodiment of a compensating element from a view looking down along the Z direction;

FIG. 4 shows a further schematic partial cross-sectional view of an embodiment of a compensating element taken along the line A-A in FIG. 3;

FIG. 5 shows a further schematic partial cross-sectional view of an embodiment of a compensating element comprising a force sensor and a test element taken along the line A-A in FIG. 3;

FIG. 6 shows a further schematic partial cross-sectional view of a further embodiment of a compensating element comprising a force sensor and a test element taken along the line A-A in FIG. 3;

FIG. 7 shows a schematic representation of the force signal during establishing and releasing a plug-in connection;

FIG. 8 shows a schematic partial view of a further embodiment of a device for testing plug-in elements of a plug-in connection comprising a deployment mechanism for moving the plug-in element receptacle;

FIG. 9 shows a schematic partial view of an embodiment of a compensating element; and

FIG. 10 shows a schematic partial view of an embodiment of a compensating element.

FIG. 11 shows an elevated perspective view of an embodiment of a compensating element shown in different views in each of FIGS. 3-6.

Throughout the figures, identical reference numerals refer to identical objects.

### DETAILED DESCRIPTION OF EXEMPLARY EMBODIMENTS OF THE INVENTION

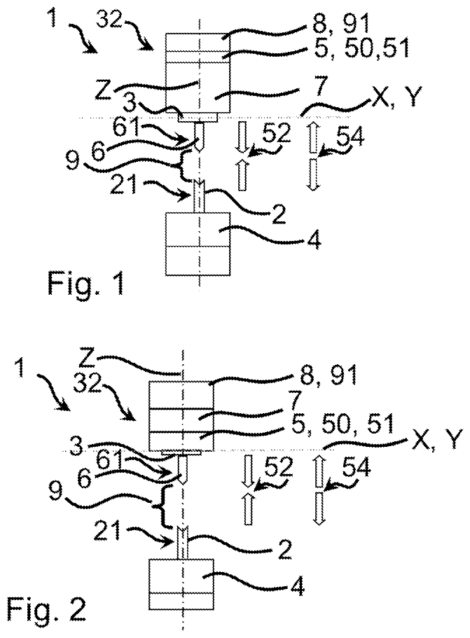

A device generally designated by the numeral 1 for testing at least one plug-in element 2 is shown in schematically FIG. 1. The device 1 comprises a plug-in element receptacle 4, which is configured for accommodating at least one plug-in element 2. The device 1 comprises at least one test element receptacle 3, which is configured for accommodating at least one test element 6. The test element receptacle 3 and the plug-in element receptacle 4 are arranged to be symmetrically in alignment with one another along a test axis Z. The test element receptacle 3 and the plug-in element receptacle 4 are movable relative to one another along the test axis Z. The test element receptacle 3 and the plug-in element receptacle 4 may be moved along the test axis towards or away from one another so that a distance 9 schematically shown in FIGS. 1 and 2 between the test element receptacle 3 and the plug-in element receptacle 4 is increased or decreased. The arrows generally designated by the numeral 52 in FIGS. 1 and 2 schematically indicates the test element receptacle 3 and the plug-in receptacle 4 moving towards each other. Similarly, the arrows generally designated by the numeral 54 in FIGS. 1 and 2 schematically indicates the test element receptacle 3 and the plug-in receptacle 4 moving away from each other.

It is also possible, however, to design the movements of the test element receptacle 3 relative to the plug-in element receptacle 4 in the shape of an arc or in other shapes, at least for short plug-in paths.

A plug-in element receptacle 4 is configured to receive a plug-in element 2 to be tested and to secure the plug-in element 2 within the plug-in element receptacle 4. After completion of the testing, the plug-in element 2 may be withdrawn. Thus, the manner of securing is designed to be reversible. The manner of securing may be achieved by a force lock, for example by using a fastening element or a clamping element. A fastening element is, for example, a screw or a nut. A clamping element is, for example, a spring or a rubber element. The manner of securing may also be achieved by a form fit. Means for securing by form fit may be designed as a split pin that engages a corresponding recess. In one embodiment, the securing means secures the plug-in element 2 and is able to withstand a force of more than 1.5 times the nominal extraction force. Typical nominal extraction forces fall within the range of 0.3 N to as much as 200 N or 300 N. However, anything over about 100 N is regarded as difficult for manual extraction. Connectors with extraction forces in the range of 0.4 N to 30 N or 50 N are more typically encountered.

A test element receptacle 3 receives the test element 6 and secures the test element 6 within the test element receptacle 3. After testing of a plug-in element 2 by the test element 6, the test element 6 remains in the test element receptacle for testing another plug-in element 2. The securing of the test element 6 is designed to be reversible. In this way, the test element 6 may be replaced, if necessary, for example for testing a different type of plug-in element. The securing of the test element 6 may be achieved by a force lock, for example by using a fastening element or a clamping element. A fastening element is, for example, a screw or a nut. A clamping element is, for example, a spring or a rubber element. The securing of the test element 6 may also be achieved by a form fit. Means for securing by form fit may be designed as a split pin that engages a corresponding recess. In one embodiment, the securing means secures the test element 6 and is able to withstand a force of more than 1.5 times the nominal extraction force.

The device 1 comprises a force sensor 5 configured to detect a force that is schematically indicated in FIGS. 1 and 2 by the numeral 50. The force 50 to be detected acts along the test axis Z during insertion, and the sensor 5 is configured to provide said force 50 in the form of a force signal 51, which accordingly is schematically indicated in FIGS. 1 and 2. A force sensor 5 that detects a force along at least one axis may be used for this purpose, for example. Various embodiments of force sensors 5 are known. Force sensors 5 may detect a force by a dimensional change of at least one strain gauge. A strain gauge-based force sensor 5 that may be used is available from Kistler's Type 4576A series. Force sensors 5 comprising piezoelectric measuring elements are also available. They are particularly suitable for detecting small dynamic forces such as those that may occur in a plugging process. During use, piezoelectric force sensors 5 are preloaded by a preload force so that tensile forces and compressive forces may be detected. An example of a piezoelectric force sensor 5 is Type 9001C or Type 9217A available from applicant Kistler. A precursor of the Type 9001C sensor is described in applicant's U.S. Pat. No. 3,614,488, which is hereby incorporated herein in its entirety for all purposes by this reference. An extraction force 54 schematically shown in FIGS. 1 and 2 is detected as a tensile force. An insertion force 52 schematically shown in FIGS. 1 and 2 is detected as a compressive force.

As schematically shown in FIGS. 1 and 2 for example, the force sensor 5 is configured and disposed to detect a force acting along the test axis Z and to provide it in the form of a force signal 51. The force signal 51 includes the insertion force 52 that arises when the plug-in connection between the plug-in element 2 and the test element 6 is established. The force signal 51 includes the extraction force that arises when the plug-in connection of the plug-in element 2 and the test element 6 is released. It is advantageous to detect the force exclusively along the test axis Z. Although force sensors exist that are able to detect forces along more than one axis, these multiple-axis sensors are more expensive than force sensors with comparable sensitivity and detecting a force along only one axis. An example of the variation of the magnitude of a force signal 51 with the distance T, which is a measure of the nominal plug-in depth of the plug-in connection, is schematically shown in FIG. 7.

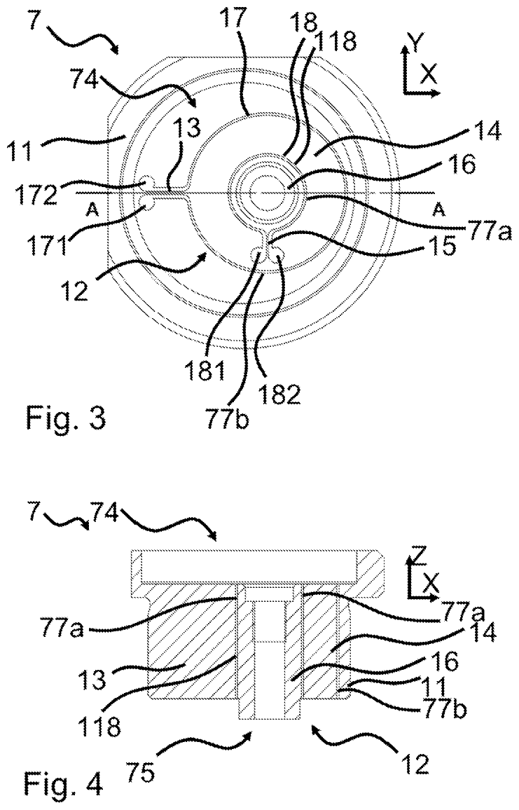

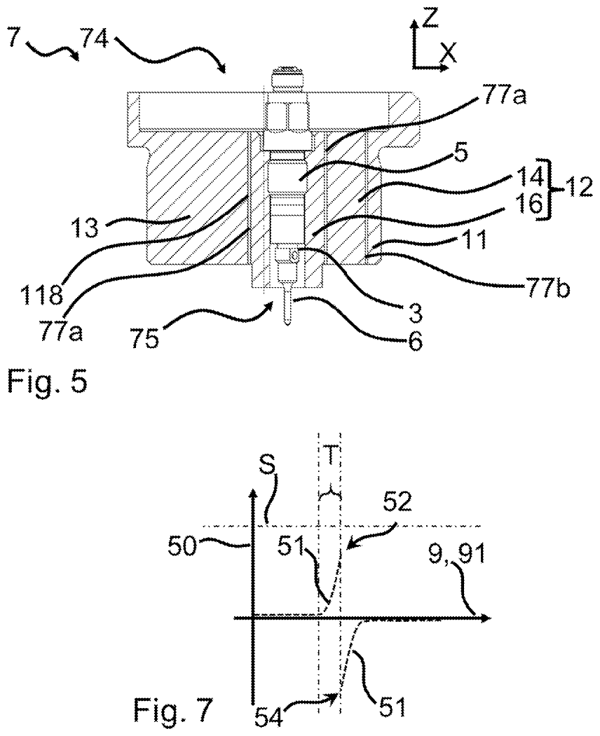

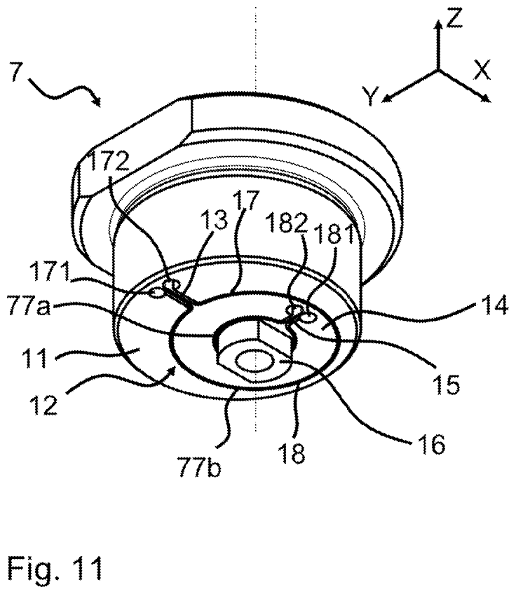

According to the invention, the device 1 comprises a compensating element 7 that is configured and disposed for compensating an offset between the plug-in element 2 and the test element 6. An embodiment of the compensating element 7, which is viewed in FIG. 3 from the second end 75 shown in FIG. 5, is shown in an elevated perspective view in FIG. 11 in which the test axis Z is shown in a dotted line. The compensating element 7 is designed to be at least partially elastic in the direction of at least one spatial axis X. The test element receptacle 3 is arranged in an operative connection with the compensating element 7 so that the test element 6 is elastically movable along the at least one spatial axis X. The test element 6 and plug-in elements 2 are secured in such a way that the test element 6 and the plug-in element 2 are substantially arranged on the test axis Z. Substantially arranged on the test axis Z is understood to mean that a plug-in connection between the test element 6 and the plug-in element 2 can be established while the test element receptacle 3 and the plug-in element receptacle 4 are moved along the test axis Z. It should be understood that the test element 6 is configured in a manner that is suitable for forming a plug-in connection with the plug-in element 2. An offset of the plug-in element 2 and the test element 6 with respect to each other has an impact on the determination of the insertion force 52 and/or the extraction force 54 so that not the minimum insertion force 52 and/or extraction force 54 is detected. The minimum insertion force 52 and/or extraction force 54 is the variable of interest to be detected. In the case of an offset, a comparison of the insertion force 52 or extraction force 52 of different plug-in elements 2 cannot be performed. If this is the case, the compensating element 7 will compensate for the offset or tilt along at least one axis provided that the axis is not parallel to the test axis. The compensation is achieved by the compensating element 7 being flexible in the direction of at least one axis, which axis is not parallel to the test axis. If the plug-in element 2 and the test element 6 are offset from or tilted against each other, they will align coaxially with each other during plugging due to the compensating element 7 being elastically deformed in the direction of at least one axis X,Y in a corresponding manner by the transverse force that occurs in the case of a tilt or an offset.

As schematically shown in the embodiment of the device 1 depicted in FIG. 2, the force sensor 5 may be arranged between the test element 6 and an embodiment of the compensating element 7, which is shown in FIG. 5. For better understanding of the arrangement, the compensating element 7 is shown in a plan view looking along the Z axis in FIG. 3, a sectional view in FIG. 5 cut along the line A-A in FIG. 3, and in an elevated perspective view in FIG. 11. In this case, due to the flexibility of the compensating element 7 in the direction of at least one axis, the force sensor 5 is elastically movable against the test axis Z along the at least one spatial axis X. As described more fully below, the configuration of the compensating element 7 can include a spring element 13 shown for example in the views of FIGS. 3-6 and 11 and/or a spring element 15 shown for example in the views of FIGS. 3 and 11.

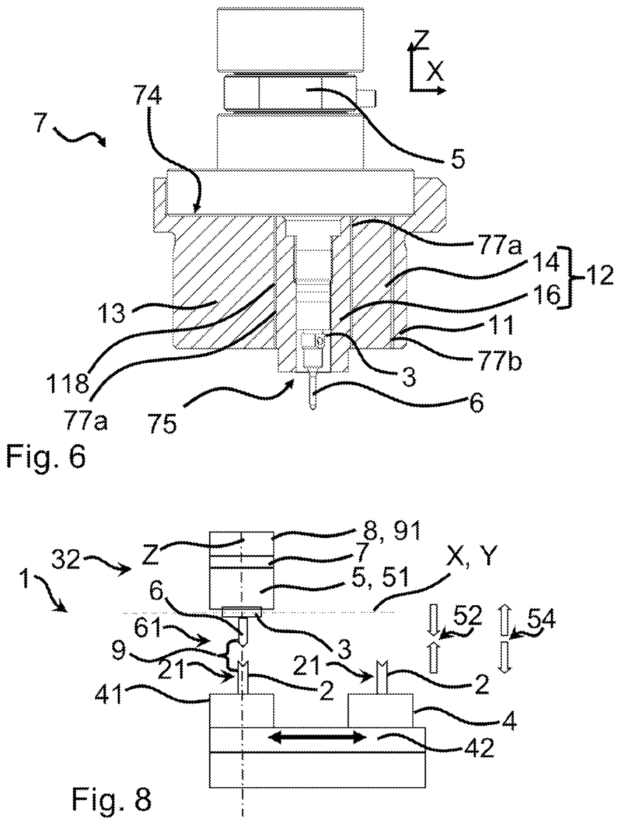

Alternatively, the force sensor 5 may be arranged on the side of the compensating element 7 that faces away from the test element 6, as schematically shown in the embodiment of the device 1 depicted in FIG. 1 and in FIG. 6. For better comprehensibility, the compensating element 7 is shown in sectional view in FIG. 6. In this embodiment of the device 1, the force sensor 5 is arranged perpendicularly to the test axis Z and is immovable in a spatial direction that lies in planes that are disposed parallel to the X,Y plane.

However, the force sensor 5 may also be arranged in a different position relative to the test part receptacle 3. It is important that the force sensor is arranged in the force path in which the insertion force 52 or extraction force 54 can be measured.

In one embodiment, the compensating element 7 comprises a peripheral portion 11 and an internal portion 12, which are shown in the view of FIG. 3. As schematically shown in FIGS. 4-6 for example, the compensating element 7 is generally defined as having a first end generally designated by the numeral 74. The compensating element 7 is further generally defined as having a second surface end disposed axially opposite the first end 74 and generally designated by the numeral 75, which is schematically designated in FIGS. 4-6.

The first end 74 is adapted to be connected to a body 32, which is schematically indicated in FIGS. 1 and 2 in its spatial disposition with respect to the compensating element 7. The second end 75 is adapted to be connected to a test element receptacle 3, which is schematically shown in FIGS. 1 and 2 as well as in FIGS. 5 and 6 for example.

The internal portion 12 is connected to the peripheral portion 11 by at least one spring element 13. The peripheral portion 11 forms part of the first end 74. The internal portion 12 may be moved in a reversible manner with respect to the peripheral portion 11 due to the flexibility of the spring element 13, which extends like a thin reed in the Z-X plane as schematically shown in FIGS. 3, 5 and 11. Since the internal portion 12 is movable against the peripheral portion 11, the compensating element 7 is provided with an elastic functionality. Alternatively from what is depicted in exemplary figures, the first end 74 may also have the shape of a cone or a hemisphere or the like.

In a variation of the embodiment of the compensating element 7 as described above, the internal portion 12 comprises a first internal portion 14 as shown in FIGS. 4, 5 and 6. In addition, the compensating element 7 comprises a second internal portion 16. The first internal portion 14 is connected to the second internal portion 16 by at least one spring element 15, which extends like a thin reed in the Z-Y plane as schematically shown in FIGS. 3 and 11 for example. The first internal portion 14 is movable with respect to the second internal portion 16 due to the flexibility of the spring element 15. This partitioning of the compensating element 7 in a peripheral portion 11, first internal portion 14 and second internal portion 16 is advantageous because the spring element 15 arranged between the first internal portion 14 and the second internal portion 16 may be designed independently of the spring element 13 arranged between the peripheral portion 11 and the first internal portion 14. Thus, the spring elements 13, 15 may have different properties with respect to spring force and/or preferred spring axis as the direction of movement. In this respect, the spring axis is the axis in which the spring element 13, 15 is elastically movable. Portions connected by a spring element 13, 15 are essentially movable along the spring axis. In some embodiments of a spring element 13, 15, the spring axis may be shaped like an arc, while in other embodiments the spring axis is defined by a straight line.

Preferably, the spring element 13, 15 is shaped like a rib. The rib-shaped spring element 13, 15 at least partially extends between the first end 74 and the second end 75. Accordingly, the compensating element 7 desirably has a spring constant 71 in the direction of the test axis Z which is higher by at least a factor of twenty than the spring constant 72, 73 of the compensating element 7 in a direction perpendicular to the test axis Z. This has the advantage that the rib-shaped spring element 13, 15 is elastic in a direction perpendicular to the test axis Z and the internal portion 12 is elastically movable with respect to the peripheral portion 11 in a direction perpendicular to the test axis Z, while the spring constant 71 in the direction of the test axis Z is comparably inflexible and the internal portion 12 is not, or only very little, elastically movable with respect to the peripheral portion 11. Very little elastically movable is understood to mean that the compensating element 7 has a spring constant 71 in the direction of the test axis Z which is at least by a factor of twenty higher than that in a direction perpendicular to the test axis Z. By means of the spring element 13, 15, the compensating element 7 has a spring constant 72, 73 in the direction perpendicular to the test axis Z along which the spring element 13, 15 is elastically movable. In the embodiment as shown in FIG. 3, the spring axis is slightly curved and thus forming an arc. Since only small deflections of the spring element 13, 15 are involved, however, the term spring axis or spatial axis will be further used in the following explanation when the deflection of a spring element 13, 15 is described. This is advantageous because a compensation of an offset of the plug-in element 2 relative to the test element 6 in the direction of the test axis Z is not necessary. Rather, it is an advantage when the compensating element 7 is designed to be as inelastic as possible in the direction of the test axis Z. If this were not the case, then the compensating element 7 would be stretched or compressed first upon establishing the plug-in connection, and that would require an otherwise unnecessary additional distance 9 during the movement of the part 4 to be tested relative to the test part 3 as schematically shown in FIGS. 1 and 2. This would complicate the evaluation or assessment, respectively, of the measurement.

A test element 6 may be chosen from already produced plug-in elements, which plug-in element 2 together with a further already produced plug-in element 2 presents an insertion force 52 corresponding to a nominal insertion force 521, and/or presents an extraction force 54 corresponding to a nominal extraction force 541. However, it is also possible to specifically produce a test element 6 which together with a further plug-in element 2 specially produced for this purpose presents an insertion force 52 corresponding to the nominal insertion force 521, and/or presents an extraction force 54 corresponding to the nominal extraction force 541. It is also possible to produce a test element 6 specifically for this purpose which together with an already produced further plug-in element 2 presents an insertion force 52 corresponding to the nominal insertion force 521, and/or presents an extraction force corresponding to the nominal extraction force 541. The test element 6 may have predetermined dimensions and may have a defined coefficient of friction.

In one embodiment of the device 1 shown in FIGS. 3 and 11 for example, the compensating element 7 is elastically movable in the direction of a first spatial axis X. The first spatial axis X extends substantially perpendicularly to the test axis Z. Furthermore, in this embodiment of the device, the compensating element 7 is further elastically movable in a second spatial axis Y. The second spatial axis Y extends substantially perpendicularly to the test axis Z. The first spatial axis X and second spatial axis Y are not parallel. Advantageously, the first spatial axis X and the second spatial axis Y define a two-dimensional, linearly independent coordinate system. This is advantageous because as schematically shown in FIG. 3, the first internal portion 14 is movable with respect to the peripheral portion 11 along the first axis X perpendicularly to the test axis Z, and the first internal portion 14 is movable with respect to the second internal portion 16 along the second axis Y perpendicularly to the test axis Z and not parallel to the first axis X. Thus, the peripheral portion 11 and the second internal portion 16 are movable relative to each other in this two-dimensional coordinate system. This means that an offset of the plug-in element 2 with respect to the test element 6, which is connected to the second internal portion 16, is compensated by the compensating element 7.

In a particularly preferred embodiment of the device 1 at present, an angle between the first spatial axis X and the second spatial axis Y is an angle between 45° and 135°. Particularly preferably at present, an angle between the first spatial axis X and the second spatial axis Y is an angle of 90°. In this arrangement of the spatial axes, the spring force required to move the second internal portion 16 with respect to the peripheral portion 11 against the spring elements 13, 15 is minimal as compared to a non-orthogonal arrangement of the first spatial axis X and the second spatial axis Y.

Preferably, the compensating element 7 is arranged between the test element receptacle 3 and a body 32, which desirably is disposed as schematically indicated generally in FIGS. 1, 2 and 8 for example. The compensating element 7 has a spring constant 71 in the direction of the test axis Z. The compensating element 7 desirably has a high spring constant 71 in the direction of the test axis Z. If the compensating element 7 comprises a peripheral portion 11, a first internal portion 14 and a second internal portion 16, wherein the first internal portion 14 is movable with respect to the peripheral portion 11 along a first axis and the second internal portion 16 is movable with respect to the first internal portion 14 along a second axis Y, then the spring constant desirably will also be high for a compensating element 7 having a spring constant 72 in the direction of the first spatial axis X as well as for the compensating element 7 having a spring constant 73 in the direction of the second spatial axis Y and for the spring constant 72 along the first spatial axis X being smaller by at least a factor of twenty compared to the spring constant 71 in the direction of the test axis Z and for the spring constant 73 along the second axis Y being smaller by at least a factor of twenty compared to the spring constant 71 in the direction of the test axis Z. A high spring constant 71 in the direction of the test axis Z is advantageous because the compensating element 7 is not excessively stretched or compressed when the plug-in connection is established, and such a high spring constant 71 prevents an unnecessary additional distance 9, which is schematically shown in FIGS. 1 and 2, when moving the plug-in element receptacle 4, which holds the part to be tested, relative to the test element receptacle 3.

Advantageously, the compensating element 7 is made of a metal or a metal alloy. The compensating element 7 is mechanically stressed since it compensates for offsets in each measurement. Therefore, metals or metal alloys are suitable as the material for a compensating element 7 because they are robust and durable. Aluminum is particularly preferred at present as the material for the compensating element 7 since aluminum is easily machinable. Spring elements 13, 15 may be easily made from aluminum, for example in the form of ribs that are shaped as thin reeds, and are robust against mechanical loads, in particular alternating loads, when the rib is bent during movement of the internal portion with respect to the peripheral portion 11 of the compensating element 7. However, other metals or metal alloys such as steels or stainless steels may also be used as materials for the compensating element 7. In this way, the spring force along the test axis Z may be easily adapted for different plug-in elements 2 having different insertion forces 52 due to different material properties.

In one embodiment, the compensating element 7 is made of plastic. This has the advantage that the compensating element 7 may be produced in a quick and cost-effective manner as an injection-molded part.

In one embodiment schematically shown in FIG. 8, the plug-in element receptacle 4 accommodates at least two plug-in elements 2. In this embodiment, the device 1 comprises a deployment mechanism 42 for moving the plug-in element receptacle 4 along at least one axis that is disposed perpendicular to the test axis Z. The deployment mechanism 42 is configured and disposed to provide each of the at least two plug-in elements 2 at a position 21 on the test axis. Thus, the plug-in element receptacle 4 is able to accommodate a plurality of plug-in elements 2 at the same time, and the extraction force and/or insertion force 52 may be detected successively for each plug-in element 2. This saves time since it is not necessary to reload the device 1 for each measurement of a plug-in element 2. A deployment mechanism 42 may be a motor-operated linear guidance, a conveyor belt, a motor-driven biaxial adjustment table or a motor-driven cross table. The deployment mechanism 42 for moving the plug-in element receptacle 4 may also be designed as a rotary table where each of the at least two plug-in elements 2 is movable in a circular trajectory R perpendicular to the test axis Z, and the deployment mechanism 42 is adapted to provide each of the at least two plug-in elements 2 at a position 21 on the test axis Z. A deployment mechanism 42 is schematically shown in FIG. 8.

In one embodiment of the device 1, the test element receptacle 3 accommodates at least two test elements 6 in a change magazine. The change magazine is adapted to provide each of the at least two test elements 6 at a position 61 on the test axis Z. This is advantageous since it shortens the set-up time when a different design of the test element 6 is required for a corresponding design of plug-in elements.

In an alternative embodiment (not shown), the test element receptacle 3 and the test element 6 may be made in one piece. In this embodiment, it is not possible to employ the change magazine as described above.

In a presently preferred embodiment, device 1 comprises an adjustment mechanism 8 schematically shown in FIGS. 1, 2, 5, 6 and 8. The test element receptacle 3 is directly or indirectly connected to the adjustment mechanism 8 in either a fixed manner or in a reversibly releasable manner. The adjustment mechanism 8 is adapted and disposed to move the test element receptacle 3 along the test axis Z so that the distance 9 between the plug-in element receptacle 4 and the test element receptacle 3 schematically shown in FIGS. 1 and 2, may be increased or decreased according to the desire of the user. An adjustment mechanism 8 desirably is a motor-driven linear guidance, for example. An example of an adjustment mechanism 8 is the Type 2157B joining module available from applicant Kistler and described for example in U.S. Pat. No. 8,733,181, which is hereby incorporated herein in its entirety for all purposes by this reference. An adjustment mechanism 8 is advantageous since connecting and/or separating the test element 6 and the plug-in element 2 may be carried out with reproducible velocity and direction along the test axis Z. Particularly the velocity should typically not exceed 300 mm/s for testing a plug-in element 2. At higher velocities, the impact of the plug-in element 2 on the test element 6 may lead to undesired vibrations in the force sensor 5, thus, falsifying the measurement. Frictional forces include a component that is dependent on velocity. Therefore, the velocity used should always be predefined to be able to compare different measurements. High velocities of more than 300 mm/s lead to excessive heating of the body to be tested and the test body, and such heating may also result in incorrect measurements. The adjustment mechanism 8 is adapted to detect a distance 9 of movement along the test axis Z schematically shown in FIGS. 1 and 2 and to provide this distance 9 in the form of a distance signal 91. This is advantageous because the insertion force 52 and/or the extraction force 54 may be detected as a function of the distance 9. Thus, the distance 9 may be detected in the plug-in process up to completion of the plug-in connection and may be compared between different plug-in elements 2. In this way, an incorrect length of a plug-in element 2 may be detected even though the plug-in element 2 exhibits an insertion force 52 and/or extraction force 54 that lies within the insertion force tolerance range or extraction force tolerance range.

Advantageously, the body 32 comprises the adjustment mechanism 8.

A compensating element 7 for use in a device 1 for testing plug-in elements 2 is preferably produced in a simple production process. The compensating element 7 desirably is generally elongated about an axis that will coincide with the test axis Z and defines a first end 74 on one opposite end along the Z axis and a second end 75 at the other opposite end along the Z axis. The compensating element 7 is made from a single piece of material, for example aluminum, a different metal or a metal alloy. Referring to FIG. 3 for example, the compensating element 7 is fabricated by removing material from the piece of material by machining, wherein said removing of material desirably includes the following steps:

Removing material between the first end 74 and the second end 75 along a curved shape so that at least one rib-shaped flexible spring element 13 is formed between the starting point 171 of the curve 17 schematically shown in FIG. 3 and the end point 172 of the curve 17. The removal of this material along the curve 17 and the two radial sectors between the curve 17 and the respective end points 171, 172 leaves a thin reed of material to form the rib that functions as the spring element 13 connecting the peripheral portion 11 and the first internal portion 14 of the compensating element 7. The resulting recess between the first and second end 75 enables the spring element 13 to flexibly connect an internal portion 12 to a peripheral portion 11.

Further removal of material between the first end 74 and the second end 75 along a curved shape 18 and the two radial sectors between the curve 18 and the respective end points 181, 182 leaves a thin reed of material to form the rib that functions as the spring element 15 connecting the first internal portion 14 and the second internal portion 16 of the compensating element 7. The at least one rib-shaped spring element 15 is left between the starting point 181 of the curve 18 and the end point 182 of the curve 18. The resulting recess between the first and second ends, 74, 75 enables the rib-shaped spring element 15 to divide the internal portion 12 into a first internal portion 14 and a second internal portion 16, wherein the first internal portion 14 is elastically connected to the second internal portion 16.

Material may be removed by chip-removing machining or wire erosion, for example.

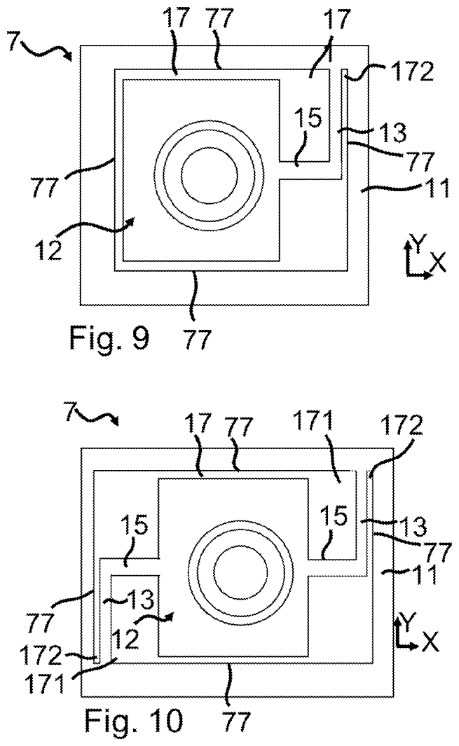

Thus, the compensating element 7 may be produced in an easy, cost-effective and quick manner. Embodiments of a compensating element 7 are schematically shown in FIG. 3 to FIG. 6 and FIG. 11 as well as in FIG. 9 and FIG. 10.

In a presently preferred embodiment of the compensating element 7, the compensating element 7 is configured to define at least one stop 77. A stop 77 is configured and disposed to limit the movement of a spring element 13, 15 in a direction perpendicular to the test axis Z. This is advantageous because a spring element 13, 15 presents a spring force only for a certain deflection, said spring force being linear with the deflection. The so-called Hooke's law stating that the spring force F is equal to the product of the deflection a and the spring constant d, i.e., F=a·d, is only valid for a predefined deflection. Excessive deflection fails to follow Hooke's law. To prevent excessive deflection of the internal portion 12 with respect to the peripheral portion 11 of the compensating element 7, the compensating element 7 defines at least one stop 77. The stop 77 further prevents excessive bending of the spring element 13, 15. Excessive bending would result if the spring element 13, 15 showed an irreversible deformation of the spring element 13, 15 after such bending. A stop 77 is, for example, a surface against which the spring element 13, 15 abuts after a certain deflection. A stop 77 is exemplarily depicted in the embodiments of a compensating element 7 shown in FIG. 3, FIG. 9 and FIG. 10. Advantageously, the compensating element 7 comprises at least one stop 77 for each spring element 13, 15. Particularly preferably at present and shown in FIGS. 3-6 and 11, the compensating element comprises two respective stops 77a, 77b, one for each respective spring element 13, 15, which stops 77a, 77b limit the movement of the respective spring element 13, 15 in both directions along the respective spatial axis X,Y.

Another embodiment of a compensating element 7 is shown in FIG. 9. The compensating element 7 comprises an internal portion 12 and a peripheral portion 11. The internal portion 12 is elastically connected to the peripheral portion by two spring elements 13, 15. A first spring element 13 is designed to be elastic along a first axis X. A second spring element 15 is designed to be elastic along a second axis Y. Similar to in the embodiment shown in FIG. 3, the spring elements 13, 15 are preferably shaped as ribs that elongate axially along the test axis Z, which is not designated in FIG. 9 but which extends into and out of the sheet of FIG. 9.

A further embodiment of a compensating element 7 is shown in FIG. 10. The compensating element 7 comprises an internal portion 12 and a peripheral portion 11. The internal portion 12 is elastically connected to the peripheral portion by two spring elements 13, 15 which are directly connected to each other. A first spring element 13 is designed to be elastic along a first axis X. A second spring element 15 is designed to be elastic along a second axis Y. In addition, the internal portion 12 is elastically connected to the peripheral portion 11 by at least two further spring elements 13, 15 wherein again a first spring element 13 is designed to be elastic along the first axis X and a second spring element 15 is designed to be elastic along the second axis Y. This embodiment of the compensating element 7 is more stable compared to the embodiment shown in FIG. 9. In this embodiment shown in FIG. 10, it is preferred to provide two connections of the peripheral portion 11 to the internal portion 12, each by two spring elements 13, 15 that elongate axially along the test axis Z, which is not designated in FIG. 10 but which extends into and out of the sheet of FIG. 10. It should be understood, however, that also more than two such connections may be considered.

In one embodiment, the force sensor 5 is a multi-component force sensor, which in addition to the insertion force acting along the test axis Z, detects at least one transverse force along a first spatial axis X or a second spatial axis Y and/or detects at least one torque. The transverse force and/or the torque are provided as an additional force signal (not shown). The additional force signal may be assessed as a quality characteristic or may be included in the calculation of the insertion force or may serve to protect the measuring device.

As schematically shown in FIGS. 1 and 2, a method is used for testing plug-in elements by a device 1 and includes the steps:

a) The test element receptacle 3 is provided at a position 61 on the test axis Z;
b) the plug-in element receptacle 4 is provided at a position 21 on the test axis Z;
c) the adjustment mechanism 8 moves the test element 6 along the test axis Z towards the plug-in element 2;
d) the force signal 51 and the distance signal 91 are continuously monitored;
d1) optionally, the amount of electrical conductance between the test element 6 and the plug-in element 2 is continuously detected as a function of the distance 9 schematically shown in FIGS. 1 and 2 by a conductance meter that is provided;
e) the force signal 51 increases upon contact of the test element 6 with the plug-in element 2; the compensating element 7 compensates for any misalignment of the test element 6 and plug-in element 2; the insertion force 52 is detected as a function of the force signal 51 over the distance 9 that is schematically shown in FIGS. 1 and 2, and the insertion force 52 is recorded;
f) the insertion force 52 at a predetermined nominal plug-in depth T is compared to a nominal insertion force 521.

If the insertion force 52 is not equal to the nominal insertion force 521 within a nominal insertion force tolerance range, then the plug-in element 2 will be discarded as being defective.

In a further embodiment of the method, the method for testing plug-in elements by a device 1 comprises additional steps which follow after steps a) to g):

h) the adjustment mechanism 8 moves the test element 6 along the test axis Z away from the plug-in element;
h1) optionally, the maximum force signal 51 is detected and recorded as the holding force 53;
i) the force signal 51 being a function of the distance signal 91 is continuously monitored and is detected until the force signal 51 drops upon a loss of contact between the test element 6 and the plug-in element 2 and is recorded as the extraction force;
j) the extraction force is compared to a nominal extraction force;
j1) optionally, the holding force 53 is compared to a nominal holding force 531.

If the extraction force 54 in step j) is not equal to the nominal extraction force 541 within a nominal extraction force tolerance range, then the plug-in element 2 will be discarded as being defective.

If the holding force 53 in the optional step j1) is not equal to the nominal holding force 531 within a nominal holding force tolerance range, then the plug-in element 2 will be discarded as being defective.

In one embodiment of the method, a locking force S is predetermined, as shown in FIG. 7. When the force signal 51 reaches the locking force S, any movement of the device 1 is stopped. This step of the method ensures that joining of the test element 6 with the plug-in element 2 occurs properly. In the case when the test element 6 is pushed too far into the plug-in element 2, there will be a natural stop which should not be reached, else the plug-in element 2 and/or the test element 6 could be damaged. This is known as “running against stop” for a pin test element and a socket plug-in element. In this way, damage to the compensating element 7 due to excessive forces of more than the locking force S is avoided.

The invention may also be employed in the automated assembly of pins in pin holes.

Of course, it is possible to combine the embodiments disclosed in this document of the device 1 with each other. Furthermore, this document also explicitly encompasses embodiments which represent a combination of the features of embodiments described herein.

### LIST OF REFERENCE NUMERALS

1 device
11 peripheral portion
12 internal portion
13 spring element
14 first internal portion
15 spring element
16 second internal portion
17 curve
171 starting point
172 end point
18 curve
181 starting point
182 end point
19 amount of electrical conductance
2 plug-in element
21 position
3 test element receptacle
32 body
4 plug-in element receptacle
5 force sensor
50 force
51 force signal
52 insertion force
521 nominal insertion force
53 holding force
531 nominal holding force
54 extraction force
541 nominal extraction force
6 test element
61 position
7 compensating element
71 spring constant along test axis
72 spring constant along first axis
73 spring constant along second axis
74 first surface
75 second surface
77 stop
79 piece of material
8 adjustment mechanism
9 distance
91 distance signal
M conductance meter
S locking force
T nominal plug-in depth
X spatial axis, first spatial axis
Y spatial axis, second spatial axis
Z test axis

What is claimed is:

1. A device for testing at least one plug-in element, the device comprising:
a test element configured for establishing a plug-in connection with the at least one plug-in element;
a plug-in element receptacle configured for receiving the at least one plug-in element;
a test element receptacle in which the test element is arranged and wherein the plug-in element receptacle and the test element receptacle are configured and disposed to be movable along a test axis for establishing the plug-in connection;
a force sensor configured and disposed to detect a force along the test axis when the plug-in connection is established and wherein the force sensor is configured to generate a force signal upon detecting the force along the test axis;
a compensating element configured and disposed for compensating for an offset between the plug-in element and the test element;
wherein the compensating element is configured to be at least partially elastic in the direction of at least one spatial axis;
wherein the test element receptacle is disposed with respective to the compensating element so that the test element is elastically movable along the at least one spatial axis.

2. The device according to claim 1, wherein the compensating element includes at least one spring element having a spring constant in the direction of a first spatial axis that is disposed in a direction that is not parallel to the test axis and wherein the at least one spring element is shaped like a rib.

3. The device according to claim 1, wherein the test element is secured in the test element receptacle in a reversible manner; wherein the plug-in element is secured in the plug-in element receptacle in a reversible manner; and wherein the test element is configured and disposed for forming a plug-in connection with the plug-in element.

4. The device according to claim 1, wherein the compensating element is elastically movable in a first spatial axis that extends substantially perpendicularly to the test axis.

5. The device according to claim 4, further comprising: a body; wherein the compensating element is arranged between the test element receptacle and the body; wherein the compensating element has a spring constant in the direction of the test axis; wherein the compensating element has a spring constant in the direction of the first spatial axis; wherein the spring constant of the first spatial axis is lower by at least a factor of twenty than the spring constant in the direction of the test axis.

6. The device according to claim 4, further comprising: a body; wherein the compensating element is arranged between the test element receptacle and the body; wherein the compensating element has a spring constant in the direction of the test axis; wherein the compensating element has a spring constant in the direction of the first spatial axis; wherein the compensating element has a spring constant in the direction of the second spatial axis; wherein the spring constant of the first spatial axis is lower by at least a factor of twenty than the spring constant in the direction of the test axis; and wherein the spring constant of the second spatial axis is lower by at least a factor of twenty than the spring constant in the direction of the test axis.

7. The device according to claim 1, wherein the compensating element is elastically movable in a first spatial axis and in a second spatial axis; wherein each of the first spatial axis and the second spatial axis extends substantially perpendicularly to the test axis; and wherein each of the first spatial axis and the second spatial axis extends substantially perpendicularly to each other to define a two-dimensional coordinate system.

8. The device according to claim 7, wherein the first spatial axis and the second spatial axis form an angle between 45° and 90°.

9. The device according to claim 7, wherein the first spatial axis and the second spatial axis form an angle between 45° and 135°.

10. The device according to claim 1, further comprising: a deployment mechanism configured and disposed for moving the plug-in element receptacle along at least one axis perpendicular to the test axis; wherein the plug-in element receptacle is configured to accommodate at least two plug-in elements; and wherein the deployment mechanism is configured to provide each of the at least two plug-in elements at a position on the test axis.

11. The device according to claim 10, wherein the test element receptacle includes a change magazine that receives the at least two test elements; and wherein the change magazine is configured to provide each of the at least two test elements at a position on the test axis.

12. The device according to claim 1, further comprising: an adjustment mechanism disposed between the test element receptacle and the plug-in element receptacle along the test axis; wherein the adjustment mechanism is configured and disposed to move along the test axis between the test element receptacle and the plug-in element receptacle for establishing the plug-in connection; and wherein the adjustment mechanism is configured to detect a distance of the movement along the test axis and to generate a distance signal that indicates the distance of movement of the adjustment mechanism between the test element receptacle and the plug-in element receptacle.

13. The device 1 according to claim 12, further comprising: at least one spring element; wherein the compensating element defines a peripheral portion that defines a first surface; wherein the compensating element defines an internal portion that defines a second surface; wherein the internal portion is connected to the peripheral portion by the at least one spring element; wherein the first surface is adapted to be connected to the adjustment mechanism; wherein the second surface is adapted to be connected to the test element receptacle; and wherein the internal portion is elastically movable with respect to the peripheral portion.

14. The device according to claim 13, wherein the internal portion defines a first internal portion; wherein the internal portion defines a second internal portion; wherein the first internal portion is connected to the second internal portion by the at least one spring element; and wherein the first internal portion is elastically movable with respect to the second internal portion.

15. The device according to claim 13, wherein the compensating element includes at least one stop that is configured and disposed to limit movement of the at least one spring element in a spatial direction perpendicular to the test axis.

16. The device according to claim 1, wherein the compensating element is made of a metal or metal alloy.

17. A method for testing a plug-in element by means of a testing device that includes a test element receptacle, a plug-in element receptable, a force sensor that generates a force signal, a test element, an adjustment mechanism that generates a distance signal, and a conductance meter, the method including the steps of:
a) providing the test element receptacle at a first position on a test axis;
b) providing the plug-in element receptacle at a second position on the test axis spaced apart from the first position;
c) using the adjustment mechanism to move the test element along the test axis towards the plug-in element;
d) continuously detecting and monitoring each of the force signal and the distance signal;
d1) wherein an amount of electrical conductance between the test element and the plug-in element is continuously monitored as a function of the distance by using the conductance meter;
e) wherein the force signal increases upon contact of the test element and the plug-in element; wherein the compensating element compensates for a misalignment of the test element and the plug-in element; wherein an insertion force is detected and monitored as a function of the force signal by means of the distance signal; and
f) wherein the insertion force at a predetermined nominal plug-in depth is compared to a nominal insertion force.

18. The method according to claim 17, further comprising the steps of:
h) moving the test element along the test axis away from the plug-in element by the adjustment mechanism;
i) detecting an extraction force by continuously detecting the force signal as a function of the distance signal until the force signal drops upon loss of contact between the test element and the plug-in element; and
j) comparing the extraction force.

19. The method according to claim 18, further comprising the step of detecting a maximum force signal as a holding force and comparing the holding force to a nominal holding force.
